(19) United States
(12) Patent Application Publication
(10) Pub. No.: US 2012/0045661 A1
(43) Pub. Date: Feb. 23, 2012

(54) RARE-EARTH-DOPED ALUMINUM-GALLIUM-OXIDE FILMS IN THE CORUNDUM-PHASE AND RELATED METHODS

(76) Inventors: Raveen Kumaran, Burnaby (CA); Thomas Tiedje, Victoria (CA); Scott E. Webster, Vancouver (CA); Shawn Penson, Vancouver (CA)

(21) Appl. No.: 13/213,065

(22) Filed: Aug. 18, 2011

Related U.S. Application Data
(60) Provisional application No. 61/375,180, filed on Aug. 19, 2010.

(51) Int. Cl. C09K 11/80; B32B 9/00; C30B 23/02; G02B 6/02

(52) U.S. Cl. 428/690; 385/123; 252/301.4 R; 117/108

(57) ABSTRACT

The invention provides a means for preparing rare-earth-doped α-(Al₁₋ₓGaₓ)₂O₃ films by molecular beam epitaxy (MBE). The invention provides a composition of matter, rare-earth-doped α-(Al₁₋ₓGaₓ)₂O₃ films, and methods to provide thin films of this material. The invention also provides a means to prepare thin film rare-earth-doped α-(Al₁₋ₓGaₓ)₂O₃, including Nd: α-(Al₁₋ₓGaₓ)₂O₃, for use in solid state lasers. Rare-earth-doped α-Ga₂O₃ and rare-earth-doped alloys of α-Ga₂O₃ and α-Al₂O₃ with the same single-crystal structure independent of Ga/Al ratio are disclosed herein.

### CROSS-REFERENCE TO RELATED APPLICATIONS

This application claims the benefit of priority to U.S. Provisional Application No. 61/375,180 filed on Aug. 19, 2010, all of which application is incorporated herein by reference in its entirety for all purposes.

### TECHNICAL FIELD

The present invention relates generally to rare-earth-doped materials and, more specifically, to alloys of sapphire and α-Ga₂O₃ doped with neodymium useful as active mediums for waveguide lasers and to related methods.

### BACKGROUND OF THE INVENTION

Solid state laser crystals (e.g. Nd:YAG, Ti:Sapphire) in the form of planar waveguides have the virtue of being more compact and more efficient than their bulk counterparts (J. Mackenzie, “Dielectric solid-state planar waveguide lasers: A review,” Selected Topics in Quantum Electronics, IEEE Journal of 13, 626-637 (2007)). The strong optical confinement possible in waveguides leads to lower threshold powers while the planar geometry offers better heat extraction and integration with semiconductor devices. Planar waveguides of popular bulk laser materials have been grown by several methods including liquid phase epitaxy and pulsed laser deposition (M. Pollnau and Y. E. Romanyuk, “Optical waveguides in laser crystals,” Comptes Rendus Physique 8, 123-137 (2007)).

Molecular beam epitaxy (MBE) is a promising alternative deposition method capable of producing epitaxial films with precise composition and structure. MBE features non-equilibrium growth conditions involving the simultaneous deposition of elemental sources. This allows for new laser materials with single-site doping of rare-earths inaccessible by bulk crystal growth methods. An example is the growth of single crystal Nd-doped sapphire (Nd:α-Al₂O₃) films, a new material with optical gain comparable to Nd:YVO₄, which is one of the highest gain solid state lasers available (R. Kumaran, S. E. Webster, S. Penson, W. Li, T. Tiedje, P. Wei, and F. Schiettekatte, “Epitaxial neodymium-doped sapphire films, a new active medium for waveguide lasers,” Opt. Lett. 34, 3358-3360 (2009)).

Accordingly, there is a need in the art for new and improved rare-earth-doped materials useful as, for example, active mediums for optical waveguide lasers, as well as to related methods. The present invention fulfills these needs and provides for further related advantages.

### SUMMARY OF THE INVENTION

In brief, the present invention relates to the growth of single-phase Nd-doped α-(Al₁₋ₓGaₓ)₂O₃ films on substrates by molecular beam epitaxy. Thus, and in an embodiment, the invention provides a composition of matter, rare-earth-doped α-(Al₁₋ₓGaₓ)₂O₃, and methods for making and using thin films of this material. The invention also provides for α-(Al₁₋ₓGaₓ)₂O₃ films, either rare-earth-doped or undoped, for use as the core and cladding layers in solid state planar waveguide lasers.

In an embodiment, the present invention is directed to rare-earth-doped α-(Al₁₋ₓGaₓ)₂O₃, where α-(Al₁₋ₓGaₓ)₂O₃ is an alloy of the corundum-phase oxides α-Al₂O₃ (sapphire) and α-Ga₂O₃ that retain the same single-crystal structure independent of Ga/Al ratio, as well as to related methods. The rare-earth-doped α-(Al₁₋ₓGaₓ)₂O₃ has a gallium content x greater than 0 up to and including 1. Rare-earth-doped α-(Al₁₋ₓGaₓ)₂O₃ is a transparent optical material with a high refractive index suitable as the core layer in a planar waveguide laser.

Thus, and in an embodiment, the present invention is directed to rare-earth-doped α-(Al₁₋ₓGaₓ)₂O₃ where the rare-earth ions are on the aluminum or gallium sites in concentrations exceeding 0.1 atomic percent. The rare-earth dopants may be neodymium (Nd), europium (Eu), terbium (Tb), erbium (Er), ytterbium (Yb), thulium (Tm), holmium (Ho), or a combination thereof. When the dopant is Nd, the rare-earth-doped α-(Al₁₋ₓGaₓ)₂O₃ crystal is capable of producing optical emission peaks at wavelengths between 880-950 nm, or between 1070-1140 nm, or between 1370-1450 nm; the crystal is also capable of producing dominant optical emission peaks that depend on the Ga content x at wavelengths between 906-910 nm, or between 1090-1096 nm, or between 1381-1390 nm; and the crystal has an absorption peak between 823-825 nm.

Thus, and in an embodiment, the present invention is directed to a method of making a rare-earth-doped α-(Al₁₋ₓGaₓ)₂O₃ crystal, comprising: providing a sapphire substrate; providing a source of aluminum; providing a source of gallium; providing a source of a rare-earth element; providing a source of oxygen; and, introducing a flux of the aluminum, gallium, oxygen and rare-earth element onto the substrate under MBE conditions to thereby yield the rare-earth-doped α-(Al₁₋ₓGaₓ)₂O₃, wherein the rare-earth-doped α-(Al₁₋ₓGaₓ)₂O₃ crystal is in the form of a deposited film on the sapphire substrate. The flux of gallium (Ga) may be adjusted relative to the flux of aluminum (Al) to yield the desired Ga content denoted by x in the formula α-(Al₁₋ₓGaₓ)₂O₃. The rare-earth-element may be neodymium (Nd), europium (Eu), terbium (Tb), erbium (Er), ytterbium (Yb), thulium (Tm), holmium (Ho), or a combination thereof. In addition, the rare-earth flux may be adjusted relative to the flux of aluminum (Al) and gallium (Ga) to yield a desired dopant concentration.

In another embodiment, the present invention is directed to an optical waveguide device in which the core is a rare-earth-doped α-(Al₁₋ₓGaₓ)₂O₃ layer and the cladding consists of α-(Al_{1-y}Ga_{y})₂O₃ layers. The core layer should have a higher gallium (Ga) content than the cladding layers to establish a refractive index contrast that supports waveguiding. The Ga content of the rare-earth-doped core will determine its optical emission properties including the refractive index and wavelength of the rare-earth emission peaks. As an alternative, the core and cladding layers may be graded by varying the Ga content across the waveguide thickness during film growth. A graded rare-earth-doped core layer will produce broader emission peaks suitable for use in tunable lasers. When the waveguide is grown on a sapphire substrate, the cladding layers may be graded in the direction towards the core with a Ga content from 0 to a Ga content matching the core-cladding interfaces. A graded-index cladding will minimize waveguide propagation loss due to interfacial roughness.

These and other aspects of the present invention will be more evident upon reference to the following detailed description and accompanying drawings.

### BRIEF DESCRIPTION OF THE DRAWINGS

FIG. 1 shows high resolution x-ray diffraction from a 120 nm thick Nd:α-Ga₂O₃ film grown on A-plane sapphire: (a) θ-2θ scan showing only a single family of corundum-phase x-ray peaks indicating that the film is single phase. (b) φ rotation scans showing that the in-plane orientation of the film matches the substrate. φ scans involve detecting off-axis peaks while the sample is rotated about its normal. (c) Reciprocal space map indicating slight mosaicity as shown by the broad film peak. Q_{X} and Q_{y} are the inverse interplanar spacings along the in-plane and out-of-plane directions respectively.

FIG. 2 shows the product of emission cross section σ and lifetime τ for Nd-doped α-Ga₂O₃ and α-Al₂O₃ films grown on A-plane sapphire. σ·τ, which is proportional to optical gain, is calculated from the emission spectra using eqn. 1. The spectra are due to Nd³⁺ transitions from the ⁴F_{3/2} manifold to the ⁴I_{9/2}, ⁴I_{11/2} and ⁴I_{13/2} manifolds respectively. Inset: Magnified plot of normalized σ·τ for emission polarized ∥ optic axis.

FIG. 3 is a reciprocal space map showing the off-axis (300) peaks for Nd-doped α-(Al₁₋ₓGaₓ)₂O₃ films grown on A-plane sapphire. Film thicknesses range from 85 nm to 165 nm. Varying the composition results in the transition of film peaks from α-Ga₂O₃ to α-Al₂O₃ in Qₓ and Q_{y}, which are the inverse interplanar spacings along the [1−1 0] and [1 1 0] (in-plane and out-of-plane) directions respectively. Al-rich films deviate from the expected linear trend indicating that instead of being fully relaxed the films are compressively strained in-plane to match the substrate. Inset: Composition dependence of the strong emission peak position (normalized).

FIG. 4 shows the wavelength shift of the dominant emission peak of Nd-doped α-(Al₁₋ₓGaₓ)₂O₃ films as a function of Ga content and unit cell volume (lower and upper horizontal axes respectively). The peak wavelength shifts linearly with the unit cell volume, which is dependent on the Ga content and film strain. When film strain is not present, the peak wavelength shifts linearly with Ga content because the Ga content also has a linear effect on the unit cell volume. Inset: Hexagonal crystal structure of corundum (unit cell in gray) showing the orientations of the x, z (in-plane) and y (out-of-plane) directions with respect to the crystal unit cell.

FIG. 5 shows exemplary device configurations of graded mixed oxides in planar waveguides.

### DETAILED DESCRIPTION OF THE INVENTION

In an aspect, the invention provides a method for growing homogeneous alloys of novel solid state laser materials of rare-earth-doped α-(Al₁₋ₓGaₓ)₂O₃ by molecular beam epitaxy (MBE), where x is greater than 0 up to and including 1. A specific example of rare-earth-doped materials prepared by the invention are Nd: α-(Al₁₋ₓGaₓ)₂O₃, where x is greater than 0 up to and including 1.

The Nd-doped α-(Al₁₋ₓGaₓ)₂O₃ films are single crystal and in the corundum phase, and have the Nd ions on the aluminum or gallium sites. In a preferred embodiment the Nd content is 1% of the cation concentration. In the context of the present invention, single-phase means only corundum-phase x-ray diffraction lines in a θ-2θ scan.

The optical emission spectra of Nd-doped α-(Al₁₋ₓGaₓ)₂O₃ films feature a collection of sharp peaks characteristic of Nd-doped crystalline hosts and are unique to Nd-doped α-(Al₁₋ₓGaₓ)₂O₃. The emission peaks are in the following ranges: 880-950 nm, 1070-1140 nm and 1370-1450 nm which correspond to Nd³⁺ transitions from the upper ⁴F_{3/2} manifold to the lower ⁴I_{9/2}, ⁴I_{11/2} and ⁴I_{13/2} manifolds respectively.

In an embodiment of the invention where the Ga content x=1, the ⁴F_{3/2} to ⁴I_{9/2}, ⁴I_{11/2} and ⁴I_{13/2} transitions of Nd-doped α-(Al₁₋ₓGaₓ)₂O₃ will have strong emission peaks at wavelengths of 906 nm, 1090 nm and 1381 nm respectively.

The invention provides for tunable control of the wavelengths of the emission peaks of the prepared materials. The volume of the unit cell is an important parameter that determines the wavelengths of the emission peaks: red-shifting under biaxial compression and blue-shifting when the volume increases with Ga-content.

Compositional tuning of Nd-doped α-(Al₁₋ₓGaₓ)₂O₃ by varying x between 0-1 yields a choice of strong emission peak between 1090-1096 nm for the ⁴F_{3/2} to ⁴I_{11/2} transition, or between 906-910 nm for the ⁴F_{3/2} to ⁴I_{9/2} transition, or between 1381-1390 nm for the ⁴F_{3/2} to ⁴I_{15/2} transition.

The invention provides for tunable control of the refractive index of the prepared materials. The refractive index of rare-earth-doped α-(Al₁₋ₓGaₓ)₂O₃ depends on the Ga content, and increases up to 1.92 at a wavelength of 1000 nm when x=1.

The refractive index difference between Ga-rich α-(Al₁₋ₓGaₓ)₂O₃ and Al-rich α-(Al₁₋ₓGaₓ)₂O₃ is suitable for optical waveguiding, and can be used to make a planar waveguide laser device with a Ga-rich rare-earth-doped α-(Al₁₋ₓGaₓ)₂O₃ core and Al-rich α-(Al_{1-y}Ga_{y})₂O₃ cladding layers. The refractive index can be controlled by creating multilayer waveguide structures consisting of two or more α-(Al₁₋ₓGaₓ)₂O₃ sublayers each with different values of x.

The tunable refractive index is useful for creating graded-index profiles by varying the Ga/Al ratio during growth. A waveguide laser device with a graded-index rare-earth-doped α-(Al₁₋ₓGaₓ)₂O₃ core will have broader emission peaks beneficial for wavelength-tunable operation or pulsed-mode operation. Graded-index α-(Al₁₋ₓGaₓ)₂O₃ may be used to create graded index cladding layers for a waveguide device, where the scattering loss will be minimized when the refractive index contrast at the core-cladding interface is low or the refractive index varies continuously from the core to the cladding with no abrupt change.

In one example of the invention, a method for the preparation of rare-earth doped α-(Al₁₋ₓGaₓ)₂O₃ films by MBE is provided, the method comprising:
Providing a substrate;
Providing a source of aluminum;
Providing a source of gallium;
Providing a source of a rare earth element;
Providing a source of active oxygen;
Introducing a flux of the aluminum, gallium, oxygen and rare earth element onto the substrate under MBE conditions

In another example of the invention rare-earth-doped α-(Al₁₋ₓGaₓ)₂O₃ may be fabricated by thin film deposition on a substrate by a method comprising the following characteristics:

a. The substrate may be sapphire with an orientation of A, M, or R-plane
i. The substrate may be annealed in a furnace to improve the surface morphology

b. The deposition technique is molecular beam epitaxy where
i. The rare-earth, Ga and Al are evaporated onto a heated substrate under excess of oxygen
   1. The source materials may be either elemental rare-earth, Al or Ga; oxide compounds of rare-earth or, Al or Ga; or a combination of elemental and compound sources
ii. Oxygen is supplied in the form of active oxygen plasma.

The rare earth elements that can be used include neodymium (Nd), europium (Eu), terbium (Tb), erbium (Er), holmium (Ho), thulium (Tm) and ytterbium (Yb).

In another example of the invention Nd-doped α-(Al₁₋ₓGaₓ)₂O₃ may be fabricated by thin film deposition on a substrate by a method comprising the following characteristics:
1) Nd-doped α-(Al₁₋ₓGaₓ)₂O₃ may be fabricated by thin film deposition on a substrate where
   a. The substrate may be sapphire with an orientation of A, M, R-plane
      i. The substrate may be annealed in a furnace to improve the surface morphology
   b. The deposition technique is molecular beam epitaxy where
      i. Nd, Ga and Al are evaporated onto a heated substrate under an overpressure of oxygen
         1. The source materials may be either elemental Nd, Ga or Al; oxide compounds of Nd, Ga, or Al; or a combination of elemental and compound sources
      ii. Oxygen is supplied in the form of active oxygen plasma.

In another example of the invention is provided a composition of matter of rare-earth-doped α-(Al₁₋ₓGaₓ)₂O₃, in which the rare-earth dopant is in the range 0.01% to 10% referenced to the concentration of Group III atoms (i.e. total of Ga and Al) in α-(Al₁₋ₓGaₓ)₂O₃

Other examples of the invention include a composition of matter comprising Neodymium-doped α-(Al₁₋ₓGaₓ)₂O₃ where the atomic concentration of Nd is between 0.01% and 10% referenced to the concentration of Group III atoms in α-(Al₁₋ₓGaₓ)₂O₃.

Other examples of the invention also provide a composition of matter, and a method of preparing that composition of matter, such that the rare earth-doped α-(GaₓAl₁₋ₓ)₂O₃ can be excited to produce an optical emission spectrum featuring sharp emission peaks. In some examples the primary emission line for Nd-doped α-(Al₁₋ₓGaₓ)₂O₃ in the infrared is at 1090 to 1096 nm and is suitable as a lasing line.

Further examples of the invention include a composition of matter comprising rare-earth-doped α-(Al₁₋ₓGaₓ)₂O₃ where the atomic concentration of the rare-earth is between 0.01% and 10% referenced to the concentration of Group III atoms in α-(Al₁₋ₓGaₓ)₂O₃ and where x can be in the range from 0 to 1.

Other examples of the invention also provide a composition of matter, and a method of preparing that composition of matter, such that the rare-earth-doped α-(Al₁₋ₓGaₓ)₂O₃ can be excited to produce an optical emission spectrum featuring sharp emission peaks. The rare-earth elements that can be used include neodymium (Nd), europium (Eu), terbium (Tb), erbium (Er), holmium (Ho), thulium (Tm) and ytterbium (Yb). Due to the chemical similarity among the various rare-earth elements other rare-earth elements which are known in the art to be useful in solid state lasers may also be incorporated into α-(Al₁₋ₓGaₓ)₂O₃ under similar growth conditions and show sharp emission spectra analogous to Nd.

The invention also provides a means to prepare graded index materials in planar waveguides of mixed oxides containing rare-earth doped α-(Al₁₋ₓGaₓ)₂O₃.

### EXAMPLES

The following examples are provided to aid in the illustration and description of the invention, without meaning to limit the invention to the materials or methods described in these examples. It should be understood that these examples are illustrative and should not be considered limiting with respect to the spirit or scope of the invention. Furthermore, alternative embodiments and means of practicing the invention will become clear to one skilled in the art by these representative examples.

The films were grown on sapphire substrates in a VG-V80H MBE system designed for semiconductors but modified for oxides with the addition of a high-throughput turbomolecular pump and SiC substrate heater. Effusion cells loaded with elemental Ga, Al and Nd sources were heated independently to generate the desired flux ratio. Nd₂O₃ powder was also tested successfully. During the growth campaign we used two different oxygen plasma sources: an in-house designed 200 W variable frequency source and a customized 13.5 MHz commercial 600 W source from SVT Associates. Substrate preparation included furnace-annealing at 1150° C. for 8 hours to generate atomically flat terraces, back-surface metallization to improve radiative heating, as well as solvent cleaning prior to loading into the MBE. We tested growth temperatures between 500-800° C. and growth rates of up to 2 nm/min. The group III metal flux was the rate limiting factor as the Nd-doping level was less than 1 atomic % relatively. Excess oxygen was supplied via a plasma source as described above with background pressures around 2×10⁻⁵ ton in the growth chamber.

We found that α-Ga₂O₃ was considerably more difficult to grow than sapphire. Any Ga on the film surface not fully oxidized tends to rapidly desorb in the form of the volatile suboxide Ga₂O. Using our in-house plasma source, we were limited to growing slowly and at low temperatures to preserve crystallinity and minimize desorption. Switching to the SVT source led to higher levels of active oxygen that mitigated Ga₂O desorption allowing us to grow hotter and faster. Above 800° C. however, the thermally stable β-Ga₂O₃ phase started to appear in the predominantly α-phased films.

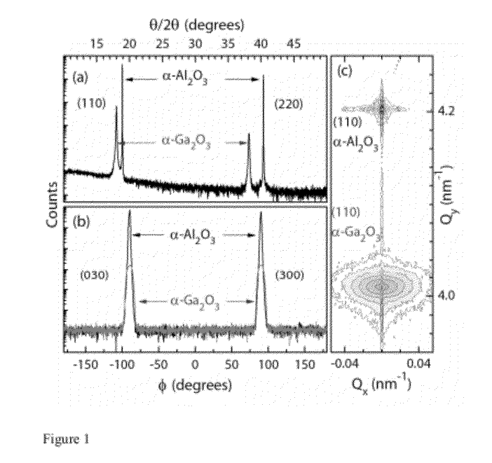

Using our novel method, we were able to grow Nd-doped α-Ga₂O₃ on R, A and M-plane sapphire substrates. Films grown on C-plane under similar conditions were entirely β-Ga₂O₃, possibly because the weaker surface diffusion on C-plane promotes the formation of other phases with lower surface energy. The structural properties of our films were characterized by high-resolution x-ray diffraction (XRD). In FIG. 1, XRD scans of an Nd: α-Ga₂O₃ film on A-plane sapphire show that the film is single crystal with slight mosaicity. The film is single phase (no β-Ga₂O₃)) and shares the crystal orientation of the substrate both in-plane and out-of-plane. From the film peaks in FIG. 1a we found that the interplanar spacing is 0.1% larger than that of bulk α-Ga₂O₃. The reciprocal space map in FIG. 1c shows that the film has a slight tilt distribution (mosaicity) centered about the substrate orientation that is consistent with columnar growth.

Since the films are single phase, the optical properties that we measured are unique to α-phase Nd: Ga₂O₃. The refractive index at a wavelength of 1 μm is 1.91 (compared with 1.75 for sapphire) as measured by broadband reflectance spectroscopy. With that index contrast, a 1 μm thick core with sapphire cladding would be sufficient to confine 92% of the fundamental TE-mode. Nd: α-Ga₂O₃ is also uniaxial like sapphire, with polarization-dependent emission either parallel or perpendicular to the hexagonal c-axis (optic axis). We collected the emission while optically pumping the 823 nm absorption peak; the equivalent Nd: α-Al₂O₃ peak is at 825 nm. The product of emission cross section σ and lifetime τ is a useful figure of merit for optical gain in a lasing material. We calculated σ·τ from the emission spectra using the equation:

$${σ}_{pol} ( λ ) \cdot τ = {\frac{3 {λ}^{5} {I}_{pol} ( λ )}{8 π {cn}^{2}} [ \int \{ 2 {I}_{⊥} ( λ ) + {I}_{‖} ( λ ) \} λ d λ ]}^{- 1} \qquad eq . 1$$

where pol is the polarization, either ⊥ or ∥ to the optic axis, λ the wavelength, n the refractive index and I the emission intensity.

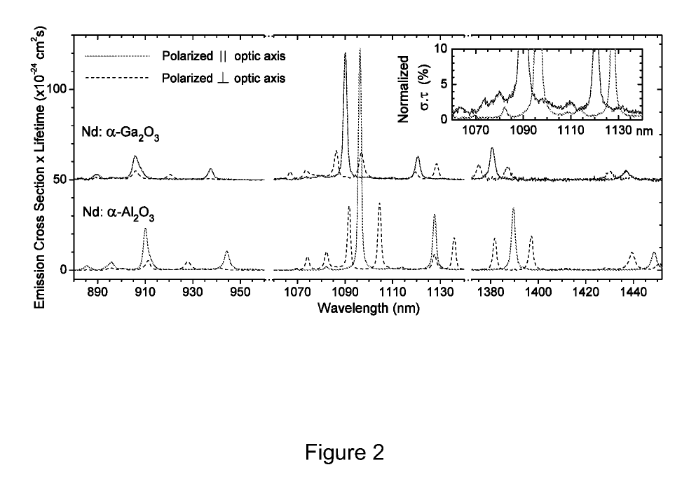

FIG. 2 compares the σ·τ of Nd: α-Ga₂O₃ to Nd: α-Al₂O₃. The polarized emission consists of a unique collection of sharp peaks characteristic of Nd-doped laser materials like Nd:YAG or Nd:YVO₄. The spectrum ∥ to the optic axis is dominant and has a strong lasing peak at 1090 nm with a σ·τ of 75×10⁻²⁴ cm²s. For comparison, the 1064 nm peak of Nd:YAG has a σ·τ of 60×10⁻²⁴ cm²s. We suspect that the 1090 nm peak could be stronger if not for the broader FWHM and higher background (FIG. 2 inset) compared to Nd:α-Al₂O₃. That weakness could be due to the relatively poorer quality of heteropitaxial vs. homoepitaxial growth. Another interesting aspect of Nd: α-Ga₂O₃ is that its peaks are essentially identical to those of Nd:α-Al₂O₃ but blue-shifted. This suggests that the local atomic bonding of the Nd³⁺ ion is similar in both cases except that the crystal field effect is mitigated for the larger Ga site causing the blue-shift.

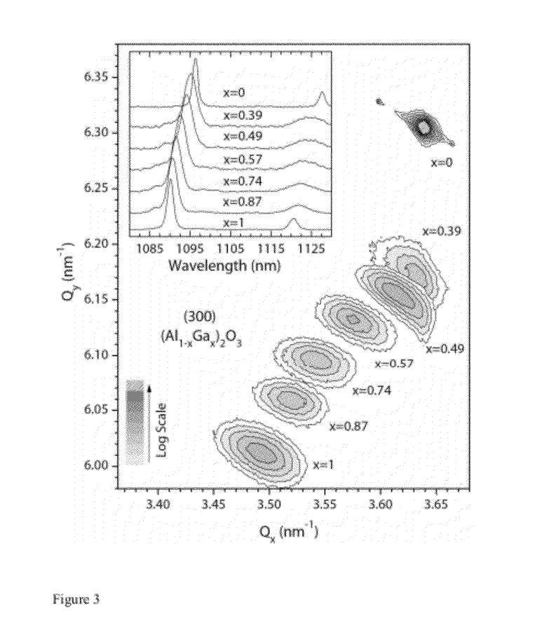

The structural and optical similarity between the two isomorphs provided a compelling case to make oxide alloys analogous to the III-V semiconductor AlGaAs. We grew a set of Nd-doped α-(Al₁₋ₓGaₓ)₂O₃ films at 800° C. under excess oxygen plasma. The composition was controlled using a fixed Ga flux with various Al fluxes, and measured post-growth by x-ray photoelectron spectroscopy. The films were 85-165 nm thick, increasing in thickness with Al content. Both XRD and optical emission measurements showed that our films were single crystal and solely in the corundum phase. FIG. 3 shows detailed scans of the structure and emission (inset), where both the x-ray and strong emission peaks shift with composition between those of the binary phases. Reciprocal space maps of the (300) off-axis peak show that both the in-plane and out-of-plane lattice constants approach that of Nd: α-Al₂O₃ with increasing Al content. The shrinking unit cell affects the local atomic bonding of the Nd³⁺ ion, moving the strong emission peak (inset) between the 1090 and 1096 nm peaks of the Nd-doped binary oxides.

Nd-doped α-(Al₁₋ₓGaₓ)₂O₃ is the first case of which the inventors are aware of a rare-earth doped binary oxide alloy suitable for making compositionally-tuned lasers. Other isomorphs used for alloying typically involve ternary oxides such as the Y₃(GaₓAl₁₋ₓ)₅O₁₂ garnets and the YₓGd₁₋ₓVO₄ vanadates. The strong 1064 nm peak of the former does not shift but is instead split up while the latter has a negligible tuning range because the peaks of both vanadates are at 1064 nm.

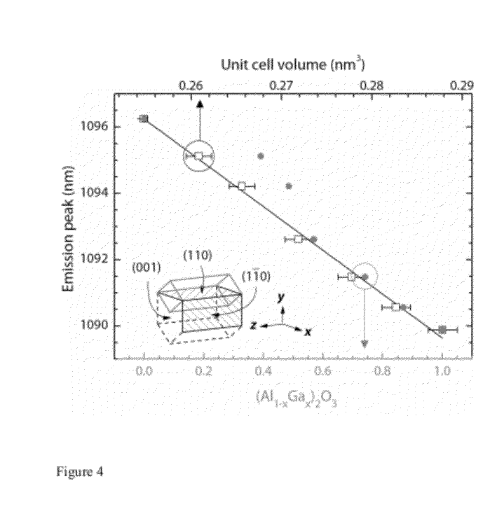

Film strain is a unique feature of epitaxial growth, occurring when the lattice mismatch to the substrate is small. The space maps in FIG. 3 shows that the Al-rich films are compressively strained in-plane and consequently relaxed out-of-plane, where Qₓ and Q_{y} shift towards α-Al₂O₃ and α-Ga₂O₃ respectively. The effect on the emission is shown by the red-shifted deviation of the strong peaks from the linear trend in FIG. 4. Such anisotropic compression has not been studied in solid state laser materials. The observed red-shift is similar to the red-shift effect observed when bulk materials are compressed hydrostatically. The emission shifts linearly with pressure, and therefore it also shifts linearly with unit cell volume, during bulk compression.

For a comparison to our films, we calculated the volume of the hexagonal unit cell (shown in the inset of FIG. 4, in gray) using the lattice constants from FIG. 3, as well as space maps of the (2 2−6) off-axis peak that resolve the lattice along the orthogonal in-plane direction Q_{z}. In FIG. 4, we show that our emission peaks correlate linearly with unit cell volume, even for Al-rich films that are biaxially compressed in-plane.

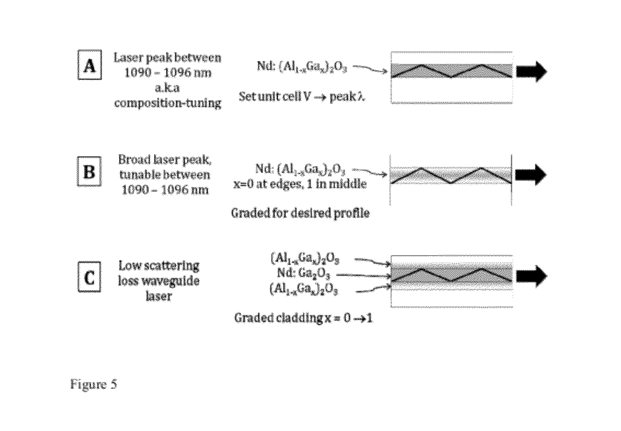

α-Ga₂O₃ has a higher refractive index than sapphire, making it suitable as the core layer in a planar waveguide. A common problem affecting current solid state planar waveguide lasers is high scattering loss at the core-cladding interface. The scattering loss is affected by the roughness at the interface and amplified by the index difference between core and cladding. Using the present invention, one can grow graded layers of α-(Al₁₋ₓGaₓ)₂O₃ such that the index contrast between the substrate (for example sapphire) and the rare earth-doped α-Ga₂O₃ core is minimal, thereby reducing the scattering losses. A similar graded cladding may be implemented on the top layer as well. FIG. 5 demonstrates some examples of these graded layers.

While the present invention has been described in the context of the embodiments illustrated and described herein, the invention may be embodied in other specific ways or in other specific forms without departing from its spirit or essential characteristics. Therefore, the described embodiments are to be considered in all respects as illustrative and not restrictive. The scope of the invention is, therefore, indicated by the appended claims rather than by the foregoing description, and all changes that come within the meaning and range of equivalency of the claims are to be embraced within their scope.

What is claimed is:

1. A single-phase rare-earth-doped α-(Al₁₋ₓGaₓ)₂O₃ crystalline material in which the Ga content denoted by x is greater than 0 up to and including 1.

2. The single-phase rare-earth-doped α-(Al₁₋ₓGaₓ)₂O₃ crystalline material according to claim 1 wherein the rare-earth-ions are on the group III atom sites and the concentration of the rare-earths exceeds 0.1 atomic percent relative to the cation concentration.

3. The single-phase rare-earth-doped α-(Al₁₋ₓGaₓ)₂O₃ crystalline material according to claim 2 wherein the material is capable of producing sharp optical emission peaks that are wavelength-tunable with unit cell volume, and wherein the unit cell volume is dependent on the Ga content.

4. The single-phase rare-earth-doped α-(Al₁₋ₓGaₓ)₂O₃ crystalline material according to claim 2 wherein the rare-earth-ions include neodymium (Nd), and wherein the Nd ion concentration exceeds 0.1 atomic percent.

5. The single-phase rare-earth-doped α-(Al₁₋ₓGaₓ)₂O₃ crystalline material according to claim 2 wherein the rare-earth-ions include neodymium (Nd), and wherein the material is capable of producing sharp optical emission peaks at wavelengths between 880-950 nm, or between 1070-1140 nm, or between 1370-1450 nm.

6. The single-phase rare-earth-doped α-(Al₁₋ₓGaₓ)₂O₃ crystalline material according to claim 2 wherein the rare-earth-ions include neodymium (Nd), and wherein the material is capable of producing a dominant optical emission peak at wavelengths between 1090-1096 nm, or between 906-910 nm, or between 1381-1390 nm, and wherein the emission peak wavelength is dependent on the material Ga content.

7. A method for making a rare-earth doped α-(Al₁₋ₓGaₓ)₂O₃ film by molecular beam epitaxy, comprising:
providing a substrate;
providing a source of aluminum;
providing a source of gallium;
providing a source of a rare-earth element;
providing a source of active oxygen; and
introducing a flux of the aluminum, gallium, oxygen and rare-earth element onto the substrate under MBE conditions.

8. The method of claim 7 wherein the substrate is sapphire with an orientation of A, M, or R-plane.

9. The method of claim 8 wherein the substrate is heated.

10. The method of claim 9 wherein the rare-earth, gallium and aluminium are deposited onto the heated substrate under an excess of oxygen.

11. The method of claim 10 wherein the rare-earth is neodymium (Nd), erbium (Er), holmium (Ho), Europium (Eu), Terbium (Tb) or ytterbium (Yb).

12. A method for making Nd-doped α-(Al₁₋ₓGaₓ)₂O₃ film by molecular beam epitaxy, comprising:
providing a substrate;
providing a source of aluminum;
providing a source of gallium;
providing a source of neodymium;
providing a source of active oxygen; and
introducing a flux of the aluminum, gallium, oxygen and neodymium onto the substrate under MBE conditions.

13. The method of claim 12 wherein the substrate is sapphire with an orientation of A, M, or R-plane.

14. The method of claim 13 wherein the substrate is heated.

15. The method of claim 14 wherein the neodymium, gallium and aluminium are deposited onto the heated substrate under an excess of oxygen.

16. An optical waveguide device in which the core is a rare-earth-doped Ga-rich α-(Al₁₋ₓGaₓ)₂O₃ layer and the cladding consists of Al-rich α-(Al_{1-y}Ga_{y})₂O₃ layers.

17. The optical waveguide device according to claim 16 wherein the Ga-rich rare-earth-doped α-(Al₁₋ₓGaₓ)₂O₃ core layer has a graded Ga/Al ratio across the layer thickness.

18. The optical waveguide device according to claim 17 wherein the rare-earth includes neodymium (Nd), and wherein the device is capable of producing a dominant optical emission peak at a wavelength between 1090-1096 nm with a width of up to 6 nm, or between 906-910 nm with a width of up to 4 nm, or between 1381-1390 nm with a width of up to 9 nm.

19. The optical waveguide device according to claim 16 wherein the Al-rich doped α-(Al₁₋ₓGaₓ)₂O₃ cladding layers have a graded Ga/Al ratio across the layer thickness.

20. The material of claim 1 wherein the crystalline material is in the form of an epitaxial film.

21. The material of claim 20 wherein the epitaxial film is on a sapphire substrate.
